(19) United States
(12) Patent Application Publication
(10) Pub. No.: US 2008/0030271 A1
(43) Pub. Date: Feb. 7, 2008

(54) Stereo Separation Adjustment Circuit And Mos Integrated Circuit Thereof

(75) Inventors: Takashi Aoyama, Kariya (JP); Hiroshi Miyagi, Yokohama (JP)

Correspondence Address: WOODCOCK WASHBURN LLP, CIRA CENTRE, 12TH FLOOR, 2929 ARCH STREET, PHILADELPHIA, PA, 19104-2891, US

(73) Assignee: Niigata Seimitsu Co., Ltd., Niigata (JP)

(21) Appl. No.: 11/630,842

(22) PCT Filed: Jun. 8, 2005
(86) PCT No.: PCT/JP05/10524

§ 371 Date: Dec. 21, 2006

(30) Foreign Application Priority Data
Jun. 25, 2004 (JP) 2004-187773

(51) Int. Cl. H03F 3/45

(52) U.S. Cl. 330/252

(57) ABSTRACT

A stereophonic separation can be adjusted without narrowing the dynamic range. Between the sources of a MOS transistor (Q5), to which a composite signal is inputted, and a MOS transistor (Q6), to which a reference voltage is inputted, there are connected in parallel the series connections of resistors and switch elements (R1) and (SW1), (R2) and (SW2), (R3) and (SW3), and so on. The separation level can be so adjusted in DC operations that the resistors (R1 to R5) may exert no influence on the output voltage of the MOS transistor (Q5), and in AC operations that the values of the parallel resistors (R1 to R5) may be varied.

### TECHNICAL FIELD

The present invention relates to a circuit for adjusting the separation level of stereo signals and to a MOS integrated circuit that includes such circuits.

### BACKGROUND ART

An FM receiver includes a stereo separation adjustment circuit which automatically reduces noise by decreasing the separation level of the right and left signals and thus makes reception close to monophonic reception when the signal strength of received FM signals is low, and which automatically performs stereo reception by increasing the separation level when the signal strength is high.

A FM receiver boarded on automobile has to include the separation adjustment circuit for removing multipath noise in order to avoid the enormous influence of the multipath noise.

Patent Document 1, for example, discloses a technique in which a number of multipath waves are detected, and the separation amount is controlled on the basis of the detected number of multipath waves in order to reduce the multipath noise in an FM receiver.

Also, the on-board FM receiver has the problem that the automatic adjustment of the stereo separation makes the sound unsteady, which is uncomfortable for listeners because the operations of increasing and decreasing the stereo separation are repeated when the reception condition changes rapidly, periodically, or intermittently. Patent Document 2 discloses a technique in which at least three characteristic curves having different separation limit values and slopes are held, and when the current electric field strength is higher than that detected previously, the characteristic curve having a separation limit value and a slope that are greater is selected.

As the stereo separation adjustment circuit, there is a circuit in which a variable current source is connected to a source side of a differential amplifier circuit consisting of MOS transistors in order to, for example, change a current value of the variable current source and to adjust the separation level. In a circuit of the above configuration, currents flowing to the MOS transistors of the differential amplifier circuit change due to the adjustment of the separation level such that the dynamic range of the output voltage becomes narrow, which is problematic.

Patent Document 1

Japanese Patent Application Publication No. 2000-49723

Patent Document 2

Japanese Patent Application Publication No. 11-298426

### DISCLOSURE OF INVENTION

It is an object of the present invention to realize an arbitrary adjustment of separation level while securing the dynamic range of output voltage.

A stereo separation adjustment circuit according to the present invention comprises a first differential amplifier circuit and a second differential amplifier circuit for differentially amplifying a signal having a prescribed frequency for demodulating a stereo composite signal, a first MOS transistor which is connected in cascade to the first differential amplifier circuit, and into the gate of which a stereo composite signal is input, a second MOS transistor which is connected in cascade to the second differential amplifier circuit, and into the gate of which a signal obtained by inverting the stereo composite signal or reference voltage is input, a switching circuit in which a plurality of circuits including resistors and switch elements are connected in parallel between the sources of the first MOS transistor and the second MOS transistor, a first current source connected to the first MOS transistor, and a second current source connected to the second MOS transistor; thereby, separation level is adjusted by turning on and off the switch elements and changing the resistance value between the sources of the first MOS transistor and the second MOS transistor.

According to the present invention, it is possible to adjust the separation level without narrowing the dynamic range of the output voltage of a stereo separation adjustment circuit.

In a stereo separation adjustment circuit according to another aspect of the present invention, the first differential amplifier circuit and the second differential amplifier circuit include four MOS transistors into the gates of which are input an alternating current signal whose frequency is twice that of the pilot signal and an inverted signal of the alternating current signal, and the switch element includes a p-channel MOS transistor and an n-channel MOS transistor connected in parallel.

By the above configuration, it is possible to demodulate the R and L signals of a stereo signal by mixing a signal whose signal level is adjusted and a signal whose frequency is twice that of the pilot signal.

A stereo separation adjustment circuit according to another aspect of the present invention comprises a first differential amplifier circuit and a second differential amplifier circuit for differentially amplifying a signal having a prescribed frequency for demodulating a stereo composite signal, a first MOS transistor which is connected in cascade to the first differential amplifier circuit, and into the gate of which a stereo composite signal is input, a second MOS transistor which is connected in cascade to the second differential amplifier circuit, and into the gate of which a signal obtained by inverting the stereo composite signal or reference voltage is input, a third MOS transistor connected between the first differential amplifier circuit and a power source, a fourth MOS transistor connected between the second differential amplifier circuit and the power source, a fifth MOS transistor through which current which is in proportion to current flowing through the third MOS transistor flows, a sixth MOS transistor through which current which is in proportion to current flowing through the fourth MOS transistor flows, a switching circuit in which a plurality of circuits including resistors and switch elements are connected in parallel between the drains of the fifth MOS transistor and the sixth MOS transistor, a third current source connected to the fifth MOS transistor, and a fourth current source connected to the sixth MOS transistor; thereby, separation level is adjusted by turning on and off the switch elements and changing the resistance value between the drains of the fifth MOS transistor and the sixth MOS transistor.

According to the present invention, it is possible to adjust the separation level without narrowing the dynamic range of the output voltage of a stereo separation adjustment circuit.

In the stereo separation adjustment circuit according to another aspect of the present invention, the third, fourth, fifth, and sixth MOS transistors include p-channel MOS transistors, and the third MOS transistor constitutes a current mirror circuit together with the fifth MOS transistor, and the fourth MOS transistor constitutes another current mirror circuit together with the sixth MOS transistor.

In the above configuration, currents which are in proportion to current flowing through the third and fourth p-channel MOS transistors flow through the fifth and sixth p-channel MOS transistors, and by changing the resistance values on their drain sides, the separation level can be adjusted.

### BRIEF DESCRIPTION OF DRAWINGS

FIG. 1 is a circuit diagram of a stereo separation adjustment circuit according to a first embodiment of the present invention; and

FIG. 2 is a circuit diagram of a stereo separation adjustment circuit according to a second embodiment of the present invention.

### BEST MODES FOR CARRYING OUT THE INVENTION

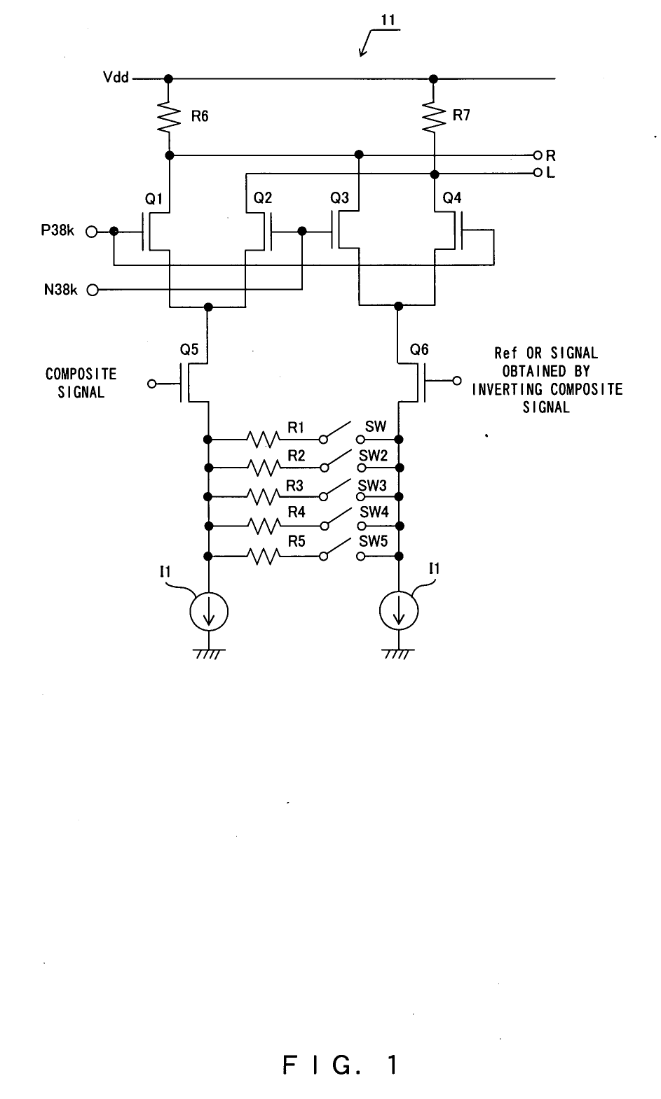

Hereinafter, embodiments of the present invention will be explained by referring to the drawings. FIG. 1 is a circuit diagram of a stereo separation adjustment circuit 11 according to a first embodiment of the present invention.

In FIG. 1, n-channel MOS transistors Q1 and Q2 constitute a differential amplifier circuit (a first differential amplifier circuit). To the gate of the n-channel MOS transistor (referred to as a MOS transistor, hereinafter) Q1, an alternating current signal P38k with a frequency of 38 kHZ, which is twice that of the pilot signal, is input. To the gate of the MOS transistor Q2, an inverted signal N38k of the signal with a frequency of 38 kHz is input.

MOS transistors Q3 and Q4 constitute another differential amplifier circuit (a second differential amplifier circuit). To the gates of the MOS transistors Q3 and Q4, the signal P38k with a frequency of 38 kHz and the signal N38k also with a frequency of 38 kHz are respectively input in a similar manner into the gates of the MOS transistors Q1 and Q2.

One terminal of a resistor R6 is connected to the drains of the MOS transistors Q1 and Q3, and the other terminal of the resistor R6 is connected to a power source Vdd. One terminal of a resistor R7 is connected to the drains of the MOS transistors Q2 and Q4, and the other terminal of the resistor R7 is connected to the power source Vdd.

The drain of a MOS transistor Q5 is connected to the sources of the MOS transistors Q1 and Q2 and the drain of a MOS transistor Q6 is connected to the sources of the MOS transistors Q3 and Q4. A stereo composite signal is input into the gate of the MOS transistor Q5 and reference voltage Ref is input into the gate of the MOS transistor Q6.

A switching circuit is connected between the sources of the MOS transistors Q5 and Q6. This switching circuit includes a resistor R1 and a switch element SW1 in series connection, a resistor R2 and a switch element SW2 in series connection, a resistor R3 and a switch element SW3 in series connection, a resistor R4 and a switch element SW 4 in series connection, and a resistor R5 and a switch element SW5 in series connection; all of these elements are further connected in parallel.

Each of the switch elements SW1 through SW5 consists of a transfer gate in which, for example, a p-channel MOS transistor and an n-channel MOS transistor are connected in parallel. A digital value obtained through an A/D conversion on a received signal strength indicator (RSSI) is fed to a control terminal (not shown) that turns on/off the switch elements SW1 through SW5, and when the received signal strength is equal to or lower than a prescribed value, a signal that decreases the separation level in accordance with the received signal strength is given.

A current source I1 is connected between the source of the MOS transistor Q5 and the ground. In addition, the current source I1 having the same output current is connected between the source of the MOS transistor Q6 and the ground.

The drains of the MOS transistors Q1 and Q3 serve as output terminals of R signals (Right signals).

The drains of the MOS transistors Q2 and Q4 serve as output terminals of L signals (Left signals).

Next, operations of the above circuits are explained. The stereo separation adjustment circuit 11 shown in FIG. 1 is a circuit that amplifies a stereo composite signal with the MOS transistor Q5, mixes the amplified signal and a signal whose frequency is 38 kHz (which is twice that of the pilot signal), and outputs the R and L signals as stereo signals.

When an FM stereo signal is demodulated, there are appropriate separation levels depending on the received signal strengths of the FM signal. The stereo separation adjustment circuit 11 in the embodiment of the present invention changes the separation level by changing the resistance values between the sources of the MOS transistors Q5 and Q6.

When the stereo composite signal is not input, the MOS transistors Q5 and Q6 have the same source potential if the same bias voltage is applied to the gates of the MOS transistors Q5 and Q6. Accordingly, none of the resistors R1 through R5 serves as a load because current does not flow through any of the resistors R1 through R5 even when any one of the switch elements SW1 through SW5 is turned on. Accordingly, none of the values of the resistors R1 through R5 influence the voltage gain of the MOS transistors Q5 or Q6.

When an FM signal is received, and the stereo composite signal is input into the gate of the MOS transistor Q5 because the MOS transistors Q5 and Q6 have different alternating source potentials, current in accordance with the potential difference between the source potentials determined by the composite signal and the reference voltage Vref, and the resistance value at the moment flows through the resistors R1 through R5 between the sources of the MOS transistors Q5 and Q6.

The voltage gain of a grounded source circuit is in proportion to the ratio of the load resistance on the drain side to the resistance (R1 through R4) on the source side when the relationship (1/gm)<<(R1˜R4) is satisfied, where gm represents mutual conductance, and (R1˜R4) represents the combined resistance of the resistors R1 through R4 on the source side. Accordingly, it is possible to change the gain of the MOS transistors Q5 and Q6 and thereby to adjust the separation level of the stereo separation adjustment circuit 11 by turning on/off the switch elements SW1 through SW5 such that the resistance value on the source side is changed.

In the above situation, even when the resistance values between the sources are changed by turning on/off the switch elements SW1 through SW5, the direct bias voltage of the MOS transistors Q5 and Q6 is not influenced; accordingly, the dynamic range of the signal output voltage of the MOS transistors Q1, Q2, Q3, and Q4 is not limited.

Also, in FIG. 1, the differential amplifier circuit can include a switching circuit by swapping the differential amplifier circuit with the MOS transistors Q5 and Q6.

The first differential amplifier circuit according to the present invention corresponds to, for example, the MOS transistors Q1 and Q2 in FIG. 1. The second differential amplifier circuit according to the present invention corresponds to, for example, the MOS transistors Q3 and Q4 in FIG. 1. Also, the first MOS transistor according to the present invention corresponds to, for example, the MOS transistor Q5 in FIG. 1. The second MOS transistor according to the present invention corresponds to, for example, the MOS transistor Q6 in FIG. 1. Also, the plurality of resistors and switch elements respectively correspond to, for example, the resistors R1 through R5 and the switch elements SW1 through SW5 in FIG. 1.

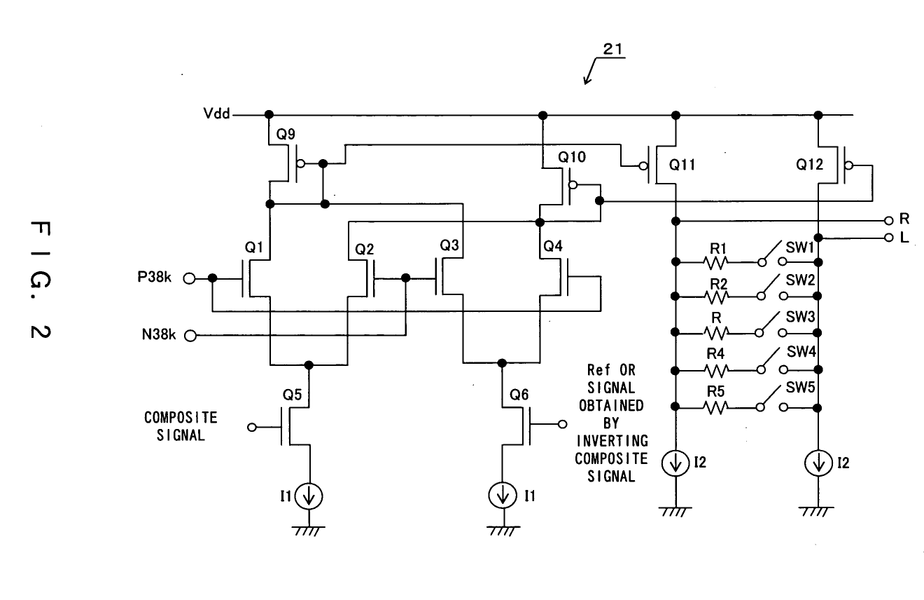

FIG. 2 is a circuit diagram of a stereo separation adjustment circuit 21 according to a second embodiment of the present invention.

In the explanation below, the elements that are the same as in FIG. 1 are denoted by the same numerals, and the explanations thereof are omitted. A p-channel MOS transistor Q9 is connected between the power source Vdd and the drains of the MOS transistors Q1 and Q3 and the gate of the p-channel MOS transistor Q9 is connected to the drains.

A p-channel MOS transistor Q10 is connected between the power source Vdd and the drains of the MOS transistors Q2 and Q4 and the gate of the p-channel MOS transistor Q10 is connected to the drains.

A p-channel MOS transistor Q11 constitutes a current mirror circuit together with the p-channel MOS transistor Q9, and their gates are connected to each other. A p-channel MOS transistor Q12 constitutes another current mirror circuit together with the p-channel MOS transistor Q10, and their gates are connected to each other.

A switching circuit is connected between the drains of the MOS transistors Q11 and Q12. This switching circuit includes the resistor R1 and the switch element SW1 in series connection, the resistor R2 and the switch element SW2 in series connection, the resistor R3 and the switch element SW3 in series connection, the resistor R4 and the switch element SW 4 in series connection, and the resistor R5 and the switch element SW5 in series connection; all of these elements are further connected in parallel.

A current source I2 is connected between the drain of the MOS transistor Q11 and the ground. Another current source I2 is connected between the drain of the MOS transistor Q12 and ground. The R signal and the L signal of the stereo signal are output from the drains of these MOS transistors Q11 and Q12.

Next, the operations of the circuit in FIG. 2 will be explained. When the stereo composite signal is not input, the same direct bias voltage is applied to the gates of the MOS transistors Q11 and Q12 and the drains of the MOS transistors Q11 and Q12 have the same potential. Accordingly, even when a resistance value is changed by turning on/off the switch elements SW1 through SW5, current does not flow through the resistors R1 through R5; thus, the direct current level of the R signal or the L signal does not change.

When the FM signal is received and the stereo composite signal is input into the gate of the MOS transistor Q5, because currents in accordance with the alternating current R and L signals flow through the MOS transistors q9 and Q10, currents in proportion to these currents flow through the MOS transistors Q11 and Q12.

When the circuit is alternating current, the drains of the MOS transistors Q11 and Q12 have different voltages; accordingly, current in accordance with the voltage differences and the resistance values flow through the resistors R1 through R5 between the drains.

The voltage gain of a grounded source circuit is in proportion to the resistance value on the drain side. Thus, the gain of the MOS transistors Q11 and Q12 can be changed by turning on/off the switch elements SW1 through SW5 such that the resistance value on the drain side is increased or decreased. Thereby, the separation level can be adjusted.

In the above situation, even when the resistance values are changed by turning on/off the switch elements SW1 through SW5, the direct output voltage of the MOS transistors Q11 and Q12 is not influenced; accordingly, the dynamic range of the output voltage of the MOS transistor Q11 or Q12 is not changed.

According to the above embodiment, it is possible to change the separation level without narrowing the dynamic range of the R and L signals of stereo. Also, it is possible to suppress the increase of circuit consumption current because direct current does not flow through the resistors R1 through R5 in which the connections can be switched by using the switch elements SW1 through SW5.

The first differential amplifier circuit according to the present invention corresponds to, for example, the MOS transistors Q1 and Q2 in FIG. 2. The second differential amplifier circuit corresponds to, for example, the MOS transistors Q3 and Q4 in FIG. 2. Also, the first MOS transistor corresponds to the MOS transistor Q5 in FIG. 2, and the second MOS transistor corresponds to the MOS transistor Q6 in FIG. 2. The fifth MOS transistor corresponds to the MOS transistor Q11 in FIG. 2, and the sixth MOS transistor corresponds to the MOS transistor Q12 in FIG. 2. Further, the plurality of resistors and switch elements correspond to the resistors R1 through R5 and to the switch elements SW1 through SW5.

The stereo separation adjustment circuit 11 or 21 described above is mounted on, for example, a semiconductor integrated circuit such as a MOS integrated circuit board for an FM radio receiver, which is fabricated by a CMOS process for forming p-channel MOS transistors and n-channel MOS transistors.

According to the present invention, it is possible to adjust the separation level without narrowing the dynamic range of a stereo separation adjustment circuit.

The present invention is not limited to the above embodiments, and can be configured as below, for example.

(1) The resistors R1 through R5 and the switch elements SW1 through SW5 do not necessarily have to be connected between the sources of the MOS transistors Q5 and Q6 in FIG. 1, but may be connected between the drains of the MOS transistors Q1 and Q4 in the figure. The switching circuit does not always have to consist of five resistors and five switch elements, but may consist of an arbitrary number of resistors and switch elements in accordance with adjustment coverage.

(2) Configurations of the separation adjustment circuits are not limited to the circuits shown in FIG. 1 or FIG. 2, and well-known circuits can be used as the separation adjustment circuit in the present invention.

(3) The present invention can be applied not only to an FM radio receiver, but also to arbitrary receivers for receiving stereo signals that are frequency modulated.

1. A stereo separation adjustment circuit, comprising:
a first differential amplifier circuit and a second differential amplifier circuit for differentially amplifying a signal having a frequency for demodulating a stereo composite signal;
a first MOS transistor which is connected in cascade to the first differential amplifier circuit, and into the gate of which a stereo composite signal is input;
a second MOS transistor which is connected in cascade to the second differential amplifier circuit, and into the gate of which a signal obtained by inverting the stereo composite signal or reference voltage is input;
a switching circuit in which a plurality of circuits including resistors and switch elements are connected in parallel between the sources of the first MOS transistor and the second MOS transistor;
a first current source connected to the first MOS transistor; and
a second current source connected to the second MOS transistor, wherein:
a separation level is adjusted by turning on and off the switch elements and changing the resistance value between the sources of the first MOS transistor and the second MOS transistor.

2. The stereo separation adjustment circuit according to claim 1, wherein:
the first differential amplifier circuit and the second differential amplifier circuit include four MOS transistors into the gates of which are input an alternating current signal whose frequency is twice that of a pilot signal and an inverted signal of the alternating current signal; and
the switch element includes a p-channel MOS transistor and an n-channel MOS transistor connected in parallel.

3. A stereo separation adjustment circuit, comprising:
a first differential amplifier circuit and a second differential amplifier circuit for differentially amplifying a signal having a frequency for demodulating a stereo composite signal;
a first MOS transistor which is connected in cascade to the first differential amplifier circuit, and into the gate of which a stereo composite signal is input; off the switch elements and changing the resistance value between the drains of the fifth MOS transistor and the sixth MOS transistor.

4. The stereo separation adjustment circuit according to claim 3, wherein:
the third MOS transistor and the fourth MOS transistor include a third p-channel MOS transistor and a fourth p-channel MOS transistor; and
the fifth MOS transistor and the sixth MOS transistor include a fifth p-channel MOS transistor and a sixth p-channel MOS transistor constituting current mirror circuits respectively together with the third p-channel MOS transistor and the fourth p-channel MOS transistor.

5. A MOS integrated circuit including a stereo separation adjustment circuit, comprising:
a first differential amplifier circuit and a second differential amplifier circuit for differentially amplifying a signal having a frequency for demodulating a stereo composite signal;
a first MOS transistor which is connected in cascade to the first differential amplifier circuit, and into the gate of which a stereo composite signal is input;
a second MOS transistor which is connected in cascade to the second differential amplifier circuit, and into the gate of which a signal obtained by inverting the stereo composite signal or reference voltage is input;
a third MOS transistor connected between the first differential amplifier circuit and a power source;
a fourth MOS transistor connected between the second differential amplifier circuit and the power source;
a fifth MOS transistor through which current that is in proportion to current flowing through the third MOS transistor flows;
a sixth MOS transistor through which current that is in proportion to current flowing through the fourth MOS transistor flows;
a switching circuit in which a plurality of circuits including resistors and switch elements are connected in parallel between the drains of the fifth MOS transistor and the sixth MOS transistor;
a third current source connected to the fifth MOS transistor; and
a fourth current source connected to the sixth MOS transistor, wherein:
a separation level is adjusted by turning on and
a second MOS transistor which is connected in cascade to the second differential amplifier circuit, and into the gate of which a signal obtained by inverting the stereo composite signal or reference voltage is input;
a switching circuit in which a plurality of circuits including resistors and switch elements are connected in parallel between the sources of the first MOS transistor and the second MOS transistor;
a first current source connected to the first MOS transistor; and
a second current source connected to the second MOS transistor, wherein:
a separation level is adjusted by turning on and off the switch elements and changing the resistance value between the sources of the first MOS transistor and the second MOS transistor.

6. A MOS integrated circuit including a stereo separation adjustment circuit, comprising:
a first differential amplifier circuit and a second differential amplifier circuit for differentially amplifying a signal having a frequency for demodulating a stereo composite signal;
a first MOS transistor which is connected in cascade to the first differential amplifier circuit, and into the gate of which a stereo composite signal is input;
a second MOS transistor which is connected in cascade to the second differential amplifier circuit, and into the gate of which a signal obtained by inverting the stereo composite signal or reference voltage is input;
a third MOS transistor connected between the first differential amplifier circuit and a power source;
a fourth MOS transistor connected between the second differential amplifier circuit and the power source;
a fifth MOS transistor through which current that is in proportion to current flowing through the third MOS transistor flows;
a sixth MOS transistor through which current that is in proportion to current flowing through the fourth MOS transistor flows;
a switching circuit in which a plurality of circuits including resistors and switch elements are connected in parallel between the drains of the fifth MOS transistor and the sixth MOS transistor;
a third current source connected to the fifth MOS transistor; and
a fourth current source connected to the sixth MOS transistor, wherein:
a separation level is adjusted by turning on and off the switch elements and changing the resistance value between the drains of the fifth MOS transistor and the sixth MOS transistor.
